(19) United States
(12) Patent Application Publication
(10) Pub. No.: US 2019/0379344 A1
(43) Pub. Date: Dec. 12, 2019

(54) FILM BULK ACOUSTIC WAVE RESONATORS AND FABRICATION METHODS THEREOF

(71) Applicant: SHANGHAI JADIC OPTOELECTRONICS TECHNOLOGY CO., LTD., Shanghai (CN)

(72) Inventor: Xiaochuan WANG, Shanghai (CN)

(21) Appl. No.: 16/395,002

(22) Filed: Apr. 25, 2019

(30) Foreign Application Priority Data
Jun. 8, 2018 (CN) 201810588325.4

(51) Int. Cl. H03H 9/02; H03H 9/17; H03H 9/13; H01L 41/08; H03H 3/02; H01L 41/332; H01L 41/29; H03H 9/56; H01L 41/047; H03H 9/10

(52) U.S. Cl. CPC H03H 9/02118; H03H 9/173; H03H 9/13; H01L 41/0805; H03H 9/02102; H03H 3/02; H03H 2003/021; H01L 41/29; H03H 9/564; H03H 9/562; H01L 41/0477; H03H 9/1042; H01L 41/332

(57) ABSTRACT

A film bulk acoustic wave resonator (BAWR) includes a first substrate; a first insulating material layer; and a first cavity, formed in the first insulating material layer. The film BAWR also includes a first electrode containing a first electrode cavity; a second electrode containing a second electrode cavity; and a first piezoelectric oscillation plate, sandwiched between the first electrode and the second electrode. Without having any parallel edges, the boundary of the first piezoelectric oscillation plate is entirely enclosed in the first cavity boundary, and at least includes an overlapping region of the boundary of the first electrode cavity and the boundary of the second electrode cavity. The film BAWR further includes a plurality of second and third piezoelectric oscillation plates, disposed between the first electrode and the second electrode to receive and absorb vibration energy transmitted out through vibration waves induced in the first electrode and the second electrode.

### CROSS-REFERENCES TO RELATED APPLICATIONS

This application claims the priority of Chinese Patent Application No. CN201810588325.4 filed on Jun. 8, 2018, the entire content of which is incorporated herein by reference.

### FIELD OF THE DISCLOSURE

The present disclosure generally relates to the field of filter technology and, more particularly, relates to film bulk acoustic wave resonators (BAWRs) and fabrication methods thereof.

### BACKGROUND

With the development of mobile communication technology, the amount of mobile data transmission has also increased rapidly. Therefore, in situations that the frequency resources are limited and mobile communication devices should be used as few as possible, improving the transmission power of wireless power transmitting devices such as wireless base stations, micro base stations, and repeaters becomes a problem that must be considered. In the meantime, this also means that the requirements on the filter power in the front-end circuits of mobile communication devices are also getting higher and higher.

At present, the high-power filters in devices such as wireless base stations are mainly cavity filters, and their power can reach hundreds of watts; however, the size of these filters is usually too large. Also, there are some devices equipped with dielectric filters, which may have an average power over 5 watts; however, the size of these filters is also very large. Because of the large size, these cavity filters cannot be integrated into the radio-frequency (RF) front-end chip.

Film filters, based on semiconductor micromachining technology and mainly including surface acoustic wave resonators (SAWRs) and bulk acoustic wave resonators (BAWRs), are able to overcome the defects of the two filters described above. In particular, BAWRs demonstrate advantages of high operating frequency, high load power, and high quality factor (Q-factor). In addition, the sizes of BAWRs are also small, which is desired for integration.

Currently, how to suppress the crosstalk between lateral spurious waves and longitudinal bulk acoustic wave signals transmitted along the c-axis direction in a BAWR remains a crucial challenge in the field of filter technology. In particular, while ensuring the connection to an external input/output electrical signal source, how to suppress the lateral resonant waves and their reflection in the piezoelectric film and also minimize the reduction of the energy consumption due to the acoustic waves propagating out from the device oscillation plate has become the focus of the industry.

The disclosed film BAWRs and fabrication methods thereof are directed to solve one or more problems set forth above and other problems in the art.

### BRIEF SUMMARY OF THE DISCLOSURE

One aspect of the present disclosure provides a film bulk acoustic wave resonator (BAWR). The film BAWR includes a first substrate; a first insulating material layer, formed on the first substrate; and a first cavity, formed in the first insulating material layer with an opening facing away from the first substrate. The first cavity forms a first cavity boundary at the surface of the first insulating material layer. The film BAWR includes a first electrode and a second electrode stacked on the first insulating material layer. The first electrode includes a first electrode cavity formed above the first cavity, and the second electrode includes a second electrode cavity formed above the first cavity. The film BAWR also includes a first piezoelectric oscillation plate sandwiched between the first electrode and the second electrode, and having a first piezoelectric-oscillation-plate boundary. At least a portion of the first piezoelectric-oscillation-plate boundary is an overlapping region of a portion of a boundary of the first electrode cavity and a portion of a boundary of the second electrode cavity, and the first piezoelectric-oscillation-plate boundary has an irregular polygonal shape without having any two edges parallel to each other, and is entirely enclosed in the first cavity boundary. The film BAWR further includes a plurality of second piezoelectric oscillation plates and a plurality of third piezoelectric oscillation plates disposed at least partially above the first cavity and sandwiched between the first electrode and the second electrode. The plurality of second piezoelectric oscillation plates and the plurality of third piezoelectric oscillation plates receive and absorb a portion of vibration energy transmitted out through vibration waves induced in the first electrode and the second electrode.

Another aspect of the present disclosure provides a fabrication method for a film BAWR. The method includes forming a first insulating material layer on a first substrate; forming a first cavity in the first insulating material layer with an opening facing away from the first substrate; and etching a portion of the first conductive film and the piezoelectric film close to an end of the sacrificial substrate to expose a portion of the second conductive film. A remaining portion of the first conductive film forms a first electrode, a plurality of trenches formed through the first conductive film and the piezoelectric film forms a plurality of first electrode cavities, and a portion of the piezoelectric film located between adjacent first electrode cavities forms a plurality of second piezoelectric oscillation plates. The method also includes bonding the first substrate and the sacrificial substrate together by bonding the first insulating material layer to the first conductive film. After bonding, the plurality of first electrode cavities are located above the first cavity. The method further includes removing the sacrificial substrate; and etching a portion of the second conductive film and a portion of the piezoelectric film close to an end of the sacrificial substrate opposite to the end where the plurality of first electrode cavities are formed to expose a portion of the first electrode. A remaining portion of the second conductive film forms a second electrode, a remaining portion of the piezoelectric film sandwiched between the first electrode and the second electrode forms a first piezoelectric oscillation plate, a plurality of trenches formed through the second conductive film and the piezoelectric film forms a plurality of second electrode cavities, and a portion of the piezoelectric film located between adjacent second electrode cavities forms a plurality of third piezoelectric oscillation plates. The first piezoelectric oscillation plate has a first piezoelectric-oscillation-plate boundary. At least a portion of the first piezoelectric-oscillation-plate boundary is an overlapping region of a portion of a boundary of the first electrode cavity and a portion of a boundary of the second electrode cavity. The first piezoelectric-oscillation-plate boundary has an irregular polygonal shape without having any two edges parallel to each other, and is entirely enclosed in the first cavity boundary. The plurality of second piezoelectric oscillation plates and the plurality of third piezoelectric oscillation plates receive and absorb a portion of vibration energy transmitted out through vibration waves induced in the first electrode and the second electrode.

Another aspect of the present disclosure provides a fabrication method for a film BAWR. The method includes forming a first insulating material layer on a first substrate; forming a first cavity in the first insulating material layer with an opening facing away from the first substrate; and forming a first sacrificial material layer in the first cavity. The top surface of the first sacrificial material layer is leveled with the top surface of the first insulating material layer. The method also includes sequentially forming a first conductive film and a piezoelectric film on the first insulating material layer and the first sacrificial material layer; and etching a portion of the piezoelectric film and a portion of the first conductive film above the first sacrificial material layer to expose a portion of the first sacrificial material layer. A plurality of trenches formed through the piezoelectric film and the first conductive film forms a plurality of first electrode cavities, a remaining portion of the first conductive film forms a first electrode, and a portion of the piezoelectric film located between adjacent first electrode cavities forms a plurality of second piezoelectric oscillation plates. The method further includes forming a second sacrificial material layer to fill the plurality of first electrode cavities; forming a second conductive film on the piezoelectric film and the second sacrificial material layer; and etching a portion of the second conductive film and a portion of the piezoelectric film formed above the first sacrificial material layer to expose a portion of the first electrode. A remaining portion of the second conductive film forms a second electrode, a remaining portion of the piezoelectric film sandwiched between the first electrode and the second electrode forms a first piezoelectric oscillation plate, a plurality of trenches formed through the second conductive film and the piezoelectric film forms a plurality of second electrode cavities, and a portion of the piezoelectric film located between adjacent second electrode cavities forms a plurality of third piezoelectric oscillation plates. The method also includes removing the first sacrificial material layer and the second sacrificial material layer. The first piezoelectric oscillation plate has a first piezoelectric-oscillation-plate boundary. At least a portion of the first piezoelectric-oscillation-plate boundary is an overlapping region of a portion of a boundary of the first electrode cavity and a portion of a boundary of the second electrode cavity. The first piezoelectric-oscillation-plate boundary has an irregular polygonal shape without having any two edges parallel to each other, and the first piezoelectric-oscillation-plate boundary is entirely enclosed in the first cavity boundary. The plurality of second piezoelectric oscillation plates and the plurality of third piezoelectric oscillation plates receive and absorb a portion of vibration energy transmitted out through vibration waves induced in the first electrode and the second electrode.

Other aspects of the present disclosure can be understood by those skilled in the art in light of the description, the claims, and the drawings of the present disclosure.

### BRIEF DESCRIPTION OF THE DRAWINGS

The following drawings are merely examples for illustrating various embodiments and are not intended to limit the scope of the present disclosure. The above and other objects, features, and advantages of the present disclosure will become more apparent from the following detailed description of the embodiments of the present disclosure with reference to the accompanying drawings. In the embodiments of the present disclosure, a same reference number generally refers to a same component.

FIG. 1 illustrates a schematic structural view of a vacuum sealed film bulk acoustic wave resonator (BAWR);

FIG. 2A and FIG. 2B illustrate schematic diagrams for analyzing film BAWR designs according to the present disclosure;

FIG. 3 illustrates a flowchart of an exemplary fabrication method for a film BAWR according to an embodiment of the present disclosure;

FIGS. 4-17 illustrate schematic views of structures at certain stages of an exemplary method for fabricating a film BAWR according to an embodiment of the present disclosure;

FIGS. 18-23 illustrate schematic views of structures at certain stages of another exemplary method for fabricating a film BAWR according to an embodiment of the present disclosure; and

FIG. 24 illustrates a flowchart of an exemplary method for fabricating a film BAWR according to another embodiment of the present disclosure.

In the figures:

R10—film bulk acoustic wave resonator (BAWR);

R100—device oscillation plate (i.e., acoustic-wave resonant plate);

R101—boundary;

R20—substrate;

R22—boundary;

R30—insulating sheet (i.e., insulating material layer);

R40—bottom cavity;

R50—lower electrode;

R60—piezoelectric oscillation plate;

R70—upper electrode;

R90—through hole;

100—first substrate;

110—first insulating material layer;

115—first cavity;

160—second dielectric layer;

201—first conductive film;

202—second conductive film;

205—piezoelectric film;

206—first temperature compensation film;

11, 12, 51, 52, 53—boundary;

210—second insulating material layer;

211—first electrode;

212—second electrode;

215—second cavity;

221—first piezoelectric oscillation plate;

222—second piezoelectric oscillation plate;

223—third piezoelectric oscillation plate;

231—first temperature compensation film;

232—second temperature compensation film;

241—first structure supporting sheet;

242—second structure supporting sheet;

261—first electrode cavity;

262—second electrode cavity;

300—sacrificial substrate;

310—first dielectric layer;

451—first sacrificial material layer;

452—second sacrificial material layer.

### DETAILED DESCRIPTION

In the following, various exemplary embodiments of the film bulk acoustic wave resonator (BAWR) and the fabrication method according to the present disclosure will be described in detail with reference to the schematic drawings. It should be understood that those skilled in the art can modify the embodiments described herein while still achieving the advantageous effects of the present disclosure. Therefore, the following description should be considered as a broad understanding of the present disclosure, and not intended to limit the scope of the present disclosure.

In the following paragraphs, the present disclosure is more specifically described through various exemplary embodiments with reference to the accompanying drawings. The advantages and features of the present disclosure will be apparent from the description and the appended claims. It should be noted that the drawings are in a simplified form and are all in a non-precise scale merely used to conveniently and clearly explain the embodiments of the present disclosure.

In the following description, it should be understood that when a layer (or film), sheet, region, pattern or structure is referred to as being on a substrate, layer (or film), sheet, region, pad and/or pattern, the layer (or film), sheet, region, pattern or structure can be located directly on another layer or substrate, and/or can be located indirectly on another layer or substrate with an insertion layer disposed between. In addition, it should be understood that when a layer is referred to as being ‘under’ another layer, it may be directly under another layer, and/or one or more insertion layers may be present. Moreover, regarding the ‘upper’ and ‘lower’ relation between different layers, reference may be made to the attached drawings.

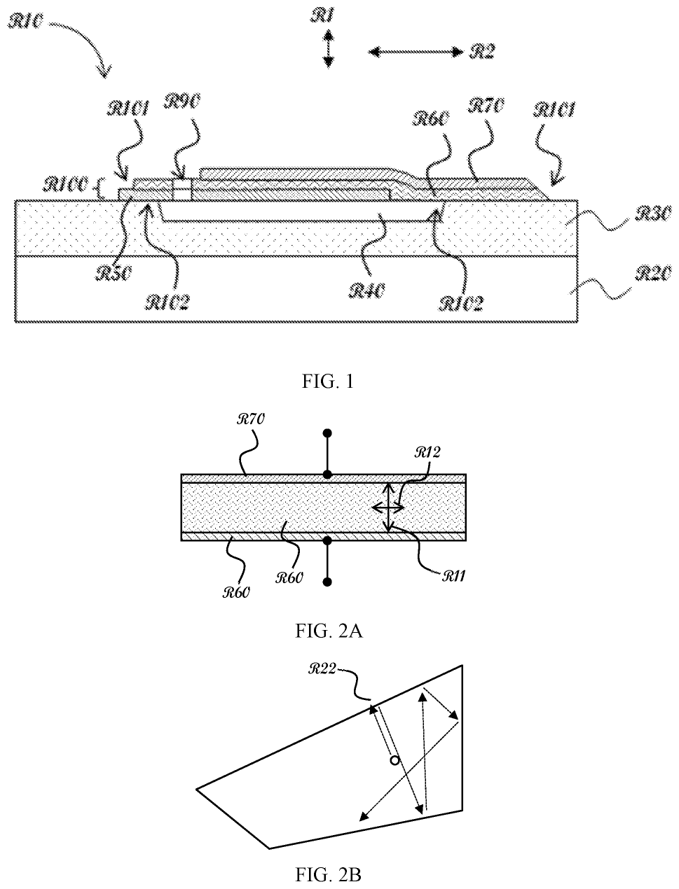

FIG. 1 illustrates a schematic structural view of a vacuum sealed film bulk acoustic wave resonator (BAWR). Referring to FIG. 1 the film BAWR R10 includes a substrate R20, an insulating sheet (i.e., an insulating material layer) R30 formed on the substrate R20, a bottom cavity R40 formed in the insulating sheet R30, and a device oscillation plate R100 formed on the substrate R20 and across the bottom cavity R40. The device oscillation plate R100 includes an upper electrode R70, a lower electrode R50, and a piezoelectric oscillation plate R60 formed between the upper electrode R70 and the lower electrode R50. A through hole R90 is formed in the device oscillation plate R100 and connected to the bottom cavity R40. The piezoelectric oscillation plate R60 is usually a piezoelectric film with the piezoelectric main axis c-axis perpendicular to the device oscillation plate R100 as well as the upper electrode R70 and the lower electrode R50.

When a constant electric field is applied to the upper and the lower surfaces of the piezoelectric film of the piezoelectric oscillation plate R60 through the upper electrode R70 and the lower electrode R50, the vertical deformation (extension or contraction) of the piezoelectric film changes with the magnitude of the electric field; when the direction of the electric field is reversed, the vertical deformation (extension or contraction) of the piezoelectric film also changes. When an alternating electric field is applied, the vertical deformation of the piezoelectric film changes between contraction and extension corresponding to the positive and the negative half cycles of the electric field, and thus generates longitudinal bulk acoustic waves propagating along the c-axis direction R1; the longitudinal acoustic waves transmitted to the interfaces between air and the upper or the lower electrode are reflected back. Therefore, the longitudinal acoustic waves are reflected back and forth inside the film such that an oscillation is generated. When the longitudinal acoustic waves propagate in a piezoelectric film with a thickness equal to an odd multiple of the half wavelength of the acoustic wave, standing wave oscillation (resonance) is generated.

However, as the longitudinal acoustic waves propagate in the piezoelectric film, due to the physical Poisson effect of the piezoelectric film, transverse deformation along the thickness direction may cause deformation in the horizontal direction R2, thereby generating lateral spurious waves in the piezoelectric film. The lateral spurious waves propagate in the horizontal direction until reflected by the boundary R102 between the bottom cavity R40 and the device oscillation plate R100 or by the boundary R101 of the piezoelectric oscillation plate R60. After the reflection, the lateral spurious waves propagate in the opposite direction R2 (i.e. in a horizontal direction opposite to the initial direction of propagation). When the lateral spurious waves also generate additional standing wave oscillations that become clutter, it may not only cause energy loss, but also stimulate longitudinal noise standing waves due to the physical Poisson effect, and thus greatly affect the quality factor of the BAWR, i.e., the Q value. At the same time, the propagation and deformation of the acoustic waves in the piezoelectric film may cause deformation and oscillation of the upper and the lower electrodes, which may be propagated and reflected, and may even induce standing waves. In addition, the deformation and oscillation of the upper and the lower electrodes may again trigger secondary acoustic waves or standing waves into the piezoelectric film, further affecting the quality factor.

Therefore, how to suppress the crosstalk between lateral spurious waves and longitudinal bulk acoustic wave signals transmitted along the c-axis direction in a BAWR remains a crucial challenge in the field of filter technology. In particular, while ensuring the connection to an external input/output electrical signal source, how to suppress the lateral resonant waves and their reflection in the piezoelectric film and also minimize the reduction of the energy consumption due to the acoustic waves propagating out from the device oscillation plate has become the focus of the industry.

FIG. 2A and FIG. 2B illustrate theoretical diagrams for analyzing film BAWR design according to the present disclosure. Theoretically, a desired BAWR may have a device design shown in FIG. 2A and FIG. 2B. The entire device oscillation plate R100 is formed by bonding three films together. The three films, namely, the upper electrode R70, the lower electrode R50, and the piezoelectric oscillation plate R60 disposed between the upper electrode R70 and the lower electrode R50 have a same size. At the same time, the upper side and the lower side of the device oscillation plate are overhead in air and vacuum, respectively. Therefore, the electric energy applied to the piezoelectric oscillation plate R60 through the upper electrode R70 and the lower electrode R50 is maximally converted to the oscillation of the piezoelectric oscillation plate R60 and the elastic vibration of the upper electrode R70 and the lower electrode R50 that are placed above and below the piezoelectric oscillation plate R60, respectively. As such, the energy consumption due to the acoustic waves propagating out from the device oscillation plate may be reduced, especially the lateral spurious waves propagating out from the device oscillation plate along the horizontal direction may be suppressed. In the meantime, referring to the top view shown in FIG. 2B, the entire device oscillation plate should have an irregular polygonal shape without having any two edges parallel to each other. As such, the standing wave oscillation caused by back and forth reflection of lateral spurious waves at any point of the piezoelectric oscillation plate R60 may be effectively prevented.

However, such an idealized BAWR is practically infeasible because not only the device oscillation plate needs to be supported appropriately, but also the upper electrode R70 and the lower electrode R50 both need to be connected to an external input/output electrical signal source.

The present disclosure provides a film BAWR and a method for fabricating the film BAWR. According to the disclosed film BAWR, a first piezoelectric oscillation plate sandwiched by a first electrode and a second electrode is entirely placed above a first cavity. The boundary of the first piezoelectric oscillation plate has an irregular polygonal shape without having any two edges parallel to each other, and thus not only the additional standing wave oscillations that become clutter in the horizontal direction may be eliminated, but also the energy consumed by the lateral spurious waves may be minimized. In the meantime, besides the first piezoelectric oscillation plate, a plurality of ‘suspended’ second piezoelectric oscillation plates and a plurality of ‘suspended’ third piezoelectric oscillation plates are placed to receive and absorb a portion of the vibration energy transmitted out through the vibration waves induced in the upper and the lower electrodes. As such, the filtering performance of the film BAWR, including the quality factor, may be effectively improved.

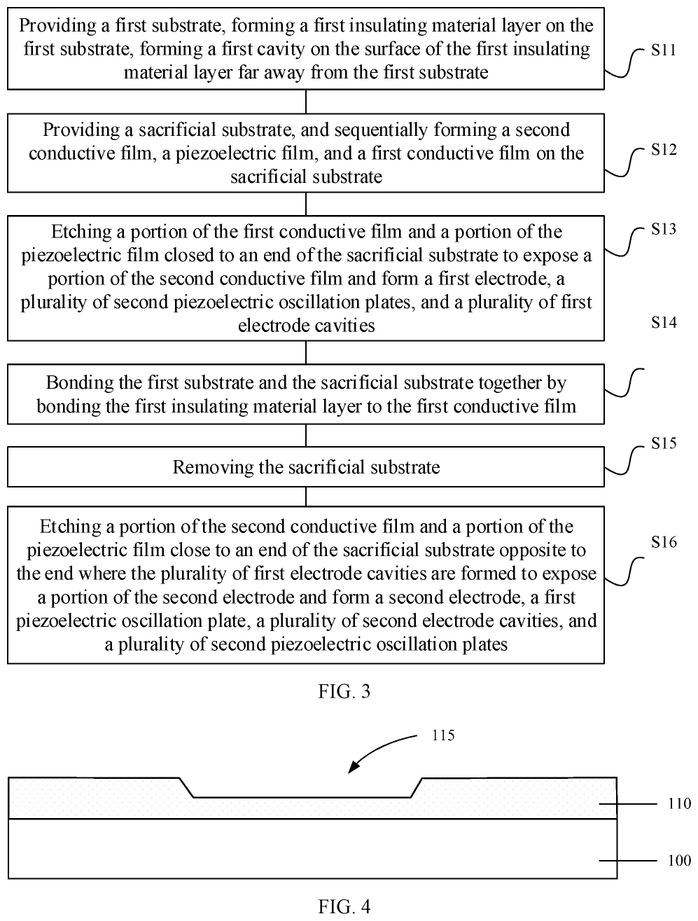

FIG. 3 illustrates a flowchart of an exemplary fabrication method for a film BAWR according to an embodiment of the present disclosure. FIGS. 4-17 illustrate schematic views of structures at certain stages of the exemplary method.

Referring to FIG. 3, at the beginning of the fabrication process for the film BAWR, a first insulating material layer may be formed on a first substrate, and a first cavity may be formed on the side surface of the first insulating material layer that faces away from the first substrate (S11). FIG. 4 illustrates a schematic cross-sectional view of a corresponding structure consistent with some embodiments of the present disclosure.

Referring to FIG. 4, a first substrate 100 may be provided. A first insulating material layer 110 may be formed on the first substrate 100. The first insulating material layer 110 may have a first surface facing the first substrate 100, and a second surface opposite to the first surface. A first cavity 115 may be formed in the first insulating material layer 110 from the second surface. That is, the first cavity 115 may have an opening on the second surface of the first insulating material layer 110.

In one embodiment, the first substrate 100 may be made of any appropriate material known to those skilled in the art. For example, the first substrate 100 may be a single-crystalline silicon substrate, a silicon germanium substrate, a germanium substrate, or any other appropriate semiconductor substrate known to those skilled in the art. According to actual needs, the first substrate 100 may include a buried structure, or a well region formed through an ion implantation process. In other embodiments, a plurality of complementary metal-oxide-semiconductor (CMOS) active devices and other electrically-interconnected components may be formed on the first substrate 100.

In one embodiment, the first insulating material layer 110 may be made of at least one of oxide, nitride, and carbide. For example, the first insulating material layer 110 may be made of silicon oxide, silicon nitride, silicon carbide, SiON, or any other appropriate material.

In one embodiment, the first insulating material layer 110 may be made of silicon oxide. The first insulating material layer 110 may be formed through a chemical vapor deposition (CVD) process. In other embodiments, the first insulating material layer 110 may be formed using a thermal oxidation method, or any other appropriate method.

The first cavity 115 may be formed through a wet etching process, a dry etching process, or a process combining the wet etching and the dry etching. The first cavity 115 may not be limited to any specific shape. For example, the first cavity 115 may have any appropriate shape, such as a rectangular shape, or other polygonal shape. The first cavity 115 may not be limited to any specific size either. For example, the height, the side length, the occupied area, etc. of the first cavity 115 may be determined according to the actual needs.

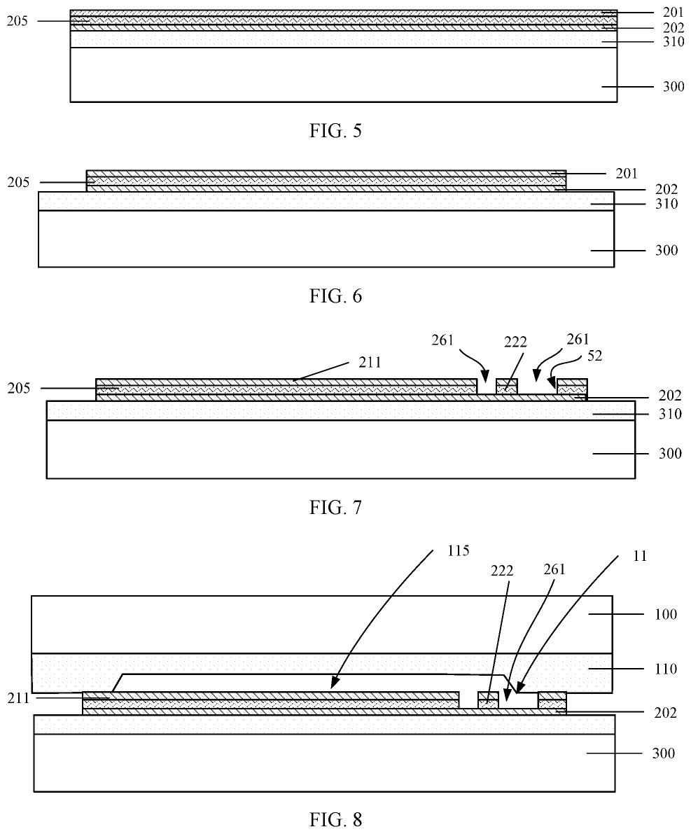

Further, referring to FIG. 3, a sacrificial substrate may be provided, and a second conductive film, a piezoelectric film, and a first conductive film may be sequentially formed on the sacrificial substrate (S12). FIG. 5 illustrates a schematic cross-sectional view of a corresponding structure consistent with some embodiments of the present disclosure.

Referring to FIG. 5, a sacrificial substrate 300 may be provided. A second conductive film 202, a piezoelectric film 205, and a first conductive film 201 may be sequentially formed on the sacrificial substrate 300.

A common substrate may be selected as the sacrificial substrate 300. For example, the sacrificial substrate 300 may be made of the same material as the first substrate 100. However, the sacrificial substrate 300 may not include CMOS active devices or other electrically-interconnected components.

In one embodiment, a first dielectric layer 310 may be formed on the sacrificial substrate 300. For example, the first dielectric layer 310 may be made of a material including at least one of oxide, nitride, and carbide. For example, the first dielectric layer 310 may be made of silicon oxide, silicon nitride, silicon carbide, SiON, or any other appropriate material.

The first dielectric layer 310 may be conducive to subsequently stripping off the sacrificial substrate 300, and in addition, the first dielectric layer 310 may also be able to serve as a temperature compensation film in subsequent steps.

In one embodiment, the first conductive film 201 and the second conductive film 202 may be made of a metal or alloy including at least one of Al, Cu, Ni, W, Ti, Mo, Ag, Au, Pt, etc.

In one embodiment, the piezoelectric film 205 may be made of a material including at least one of piezoelectric crystal or piezoelectric ceramic. For example, the piezoelectric film 205 may be made of at least one of quartz, lithium gallate, lithium germanate, titanium germanate, lithium niobate, lithium tantalate, aluminum nitride, zinc oxide, and lead-zinc titanite.

In one embodiment, the second conductive film 202, the piezoelectric film 205, and the first conductive film 201 may be modified and adjusted to desired pattern ranges according to actual needs. In addition, the edge portions of the films with undesired quality may also be removed. FIG. 6 illustrates a schematic cross-sectional view of a structure obtained after modifying and adjusting the second conductive film, the piezoelectric film, and the first conductive film. Referring to FIG. 6, the edge portions of the second conductive film 202, the piezoelectric film 205, and the first conductive film 201 may be removed.

Further, returning to FIG. 3, a portion of the first conductive film and the piezoelectric film close to one end of the sacrificial substrate may be removed through etching to expose a portion of the second conductive film, such that a first electrode, a plurality of second piezoelectric oscillation plates, and a plurality of first electrode cavities may be formed (S13). FIG. 7 illustrates a schematic cross-sectional view of a corresponding structure consistent with some embodiments of the present disclosure.

Referring to FIG. 7, a portion of the first conductive film 201 (referring to FIG. 6) and a portion of the piezoelectric film 205 (referring to FIG. 6) close to an end of the sacrificial substrate 300 may be removed through etching to expose a portion of the second conductive film 202. As such, a remaining portion of the first electrode film may become a first electrode 211, a plurality of trenches formed through the first electrode 211 (i.e., the first conductive film 201) and the piezoelectric film 205 may become a plurality of first electrode cavities 261, and a portion of the piezoelectric film 205 remained between adjacent first electrode cavities 261 may become a plurality of second piezoelectric oscillation plates 222.

In one embodiment, removing the portion of the first conductive film and the portion of the piezoelectric film 205 to form the first electrode 211, the plurality of second piezoelectric oscillation plates 222, and the plurality of first electrode cavities 261 may include the following exemplary steps.

First, a portion of the first conductive film closed to an end of the sacrificial substrate 300 may be removed through an etching process to expose a portion of the piezoelectric film 205. A remaining portion of the first conductive film may become a first electrode 211. The etching process may be a dry etching or a wet etching process.

When etching the first conductive film through, for example, a wet etching process, a photoresist layer may be used as an etch mask. In one embodiment, the photoresist layer may be patterned to a desired shape. For example, the patterned photoresist layer may expose a plurality of non-parallel edges on the first conductive film.

After etching the first conductive film, the piezoelectric film 205 may be further etched to expose a portion of the second conductive film 202. In one embodiment, the piezoelectric film 205 may be etched using the photoresist layer or the remaining portion of the first conductive film 201 (i.e., the first electrode 211) as an etch mask. That is, after removing the portion of the first conductive film 201, the etching process may be continuously performed to remove the portion of the piezoelectric film 205.

As such, the fabrication of the first electrode 211 may be completed. In addition, when the plurality of first electrode cavities 261 are formed, a portion of the piezoelectric film 205 located between adjacent first electrode cavities 261 of the plurality of first electrode cavities 261 may simultaneously become a plurality of second piezoelectric oscillation plates 222. The number of the second piezoelectric oscillation plates 222 may be more than one.

In one embodiment, serving as a ‘suspended’ mass, the plurality of second piezoelectric oscillation plates 222 may be able to receive and absorb a portion of the vibration energy transmitted out through the vibration waves induced in the upper and the lower electrodes. As such, the filtering performance of the film BAWR, including the quality factor, may be effectively improved.

The boundary of the plurality of second piezoelectric oscillation plates 222 may be a second piezoelectric-oscillation-plate boundary 52.

Further, the shapes of the plurality of second piezoelectric oscillation plates 222 may be specially designed. For example, when the second piezoelectric-oscillation-plate boundary 52 contains parallel edges, standing wave reflection may be generated inside the second piezoelectric oscillation plates 222. Therefore, the reception and absorption of the energy of vibration waves may be effectively ‘restrained’, and thus the noise signals can be more effectively reduced.

The number of the second piezoelectric oscillation plates 222 that have special shapes may be one or more than one. For example, all or a portion of the plurality of second piezoelectric oscillation plates 222 may have special shapes. In a case where a portion of the plurality of second piezoelectric oscillation plates 222 have special shapes, the shapes of the other portion of the second piezoelectric oscillation plates 222 may be circular, triangular, etc.

Further, returning to FIG. 3, the first substrate and the sacrificial substrate may be bonded together by bonding the first insulating material layer to the first electrode (S14). FIG. 8 illustrates a schematic cross-sectional view of a corresponding structure consistent with some embodiments of the present disclosure.

Referring FIG. 8, the first substrate 100 and the sacrificial substrate 300 may be bonded together by bonding the first insulating material layer 110 to the first conductive film (i.e., the first electrode 211). The bonding process may be any appropriate bonding process according to the current technology.

In one embodiment, after bonding the first substrate 100 and the sacrificial substrate 300 together, a portion of the orthogonal projection of the first electrode cavity 261 on the first substrate 100 may fall into the range of the orthogonal projection of the first cavity 115 on the first substrate 100, and another portion of the orthogonal projection of the first electrode cavity 261 on the first substrate 100 may fall outside the range of the orthogonal projection of the first cavity 115 on the first substrate 100. That is, at the etched end, a first-cavity boundary 11 of the first cavity 115 may fall on one or more first electrode cavities, and at the un-etched end, the orthogonal projection of the first electrode cavities may be able to completely contain the first-cavity boundary 11 of the first cavity 115.

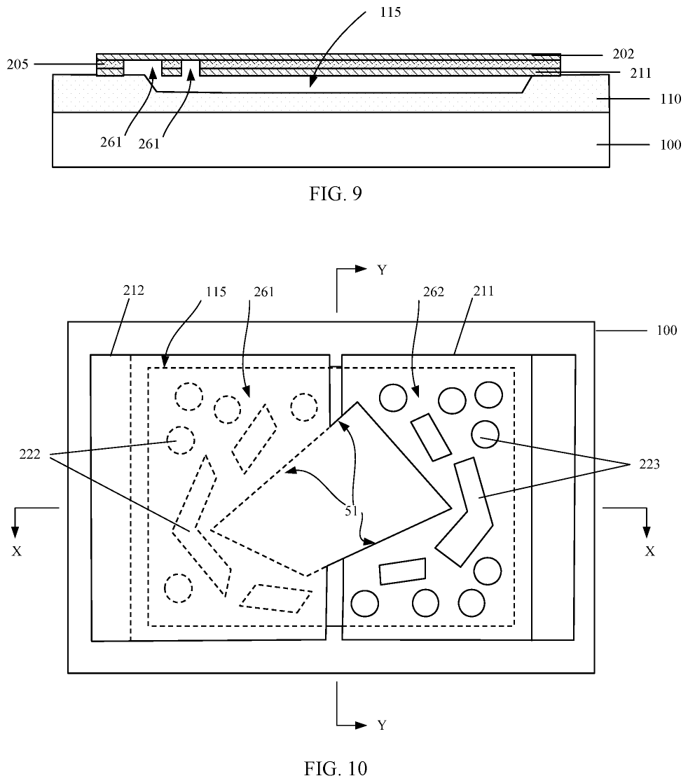

Further, returning to FIG. 3, the sacrificial substrate may be removed (S15). FIG. 9 illustrates a schematic cross-sectional view of a corresponding structure consistent with some embodiments of the present disclosure.

Referring to FIG. 9, the sacrificial substrate 300 (referring to FIG. 8) may be removed. The sacrificial substrate may be removed using a common method, such as a chemical method or a physical method. The chemical method may be a method of eroding the first dielectric layer 310, and the physical method may a method of grinding, cutting, etc.

In one embodiment, the first dielectric layer 310 may be formed, and accordingly, after removing the sacrificial substrate, the first dielectric layer 310 may be removed.

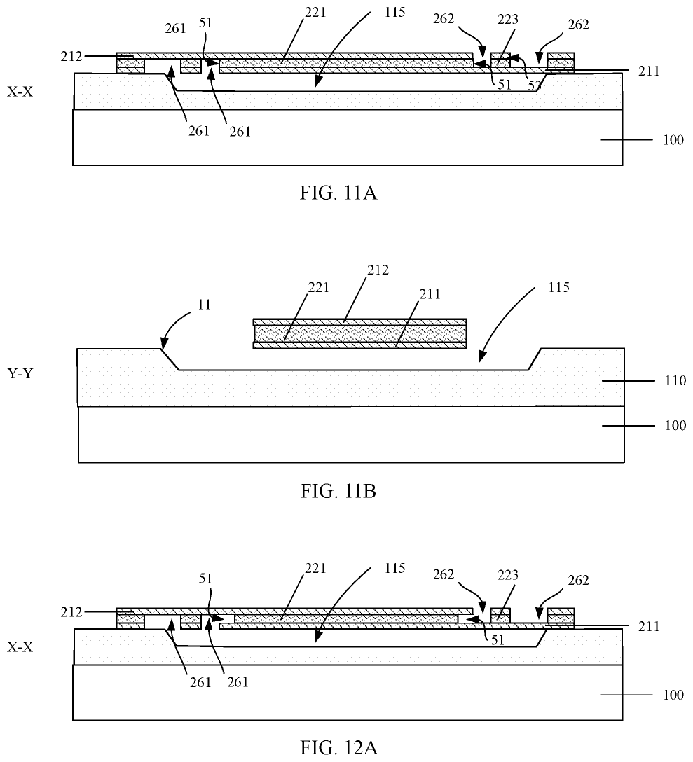

Further, returning to FIG. 3, a portion of the second conductive film and the piezoelectric film close to another end may be etched to expose a portion of the first electrode, and thus form a second electrode, a first piezoelectric oscillation plate, a plurality of third piezoelectric oscillation plates, and a plurality of second electrode cavities (S16). FIG. 10 illustrates a schematic top view of a corresponding structure obtained after etching the portion of the second conductive film and the piezoelectric film to form the second electrode, the first piezoelectric oscillation plate, the plurality of third piezoelectric oscillation plates, and the plurality of second electrode cavities. FIG. 11A illustrates a schematic cross-sectional view of the structure shown in FIG. 10 along an X-X direction, and FIG. 11B illustrates a schematic cross-sectional view of the structure shown in FIG. 10 along a Y-Y direction.

Referring to FIGS. 10-11B, a portion of the second conductive film 202 and the piezoelectric film 205 close to an end opposite to the end where the plurality of first electrode cavities 261 are formed may be etched to expose a portion of the first electrode 211. As such, a remaining portion of the second electrode film may become a second electrode 212, a plurality of trenches formed through the second electrode 212 (i.e., the second conductive film 202) and the piezoelectric film 205 may become a plurality of second electrode cavities 262, a portion of the piezoelectric film 205 sandwiched by the first electrode 211 and the second electrode 212 may become a first piezoelectric oscillation plate 221, and a portion of the piezoelectric film 205 remained between adjacent second electrode cavities 262 may become a plurality of third piezoelectric oscillation plates 223. Here, the etching process performed in step S16 may be similar to the etching process performed in step S13. Those skilled in the art should understand the implementation of the present step, and thus the details of the step are not repeated here.

Accordingly, when the plurality of second electrode cavities 262 are formed, a portion of the piezoelectric film 205 located between adjacent second electrode cavities 262 of the plurality of second electrode cavities 262 may simultaneously become a plurality of third piezoelectric oscillation plates 223. The number of the third piezoelectric oscillation plates 223 may be more than one.

In one embodiment, serving as a ‘suspended’ mass block, the plurality of third piezoelectric oscillation plates 223 may be able to receive and absorb a portion of the vibration energy transmitted out through the vibration waves induced in the upper and the lower electrodes. As such, the filtering performance of the film BAWR, including the quality factor, may be effectively improved.

The boundary of the plurality of third piezoelectric oscillation plates 223 may be a third piezoelectric-oscillation-plate boundary 53.

Further, the shapes of the plurality of third piezoelectric oscillation plates 223 may be specially designed. For example, when the third piezoelectric-oscillation-plate boundary 53 contains parallel edges, standing wave reflection may be generated inside the third piezoelectric oscillation plates 223. Therefore, the reception and absorption of the energy of vibration waves may be effectively ‘restrained’, and thus the noise signals can be more effectively reduced.

The number of the third piezoelectric oscillation plates 223 that have special shapes may be one or more than one. For example, all or a portion of the plurality of third piezoelectric oscillation plates 223 may have special shapes. In a case where a portion of the plurality of third piezoelectric oscillation plates 223 have special shapes, the shapes of the other portion of the third piezoelectric oscillation plates 223 may be circular, triangular, etc.

After etching, the boundary of the first piezoelectric oscillation plate 221 may be a first piezoelectric-oscillation-plate boundary 51, and the first piezoelectric-oscillation-plate boundary 51 may have an irregular polygonal shape without having any two edges parallel to each other. The first piezoelectric-oscillation-plate boundary 51 may be completely enclosed within the boundary of the first cavity 115 (i.e. the first-cavity boundary 11). The plurality of second piezoelectric oscillation plates 222 and the plurality of third piezoelectric oscillation plates 223 may receive and absorb a portion of the vibration energy transmitted out through the vibration waves induced in the first electrode 211 and the second electrode 212.

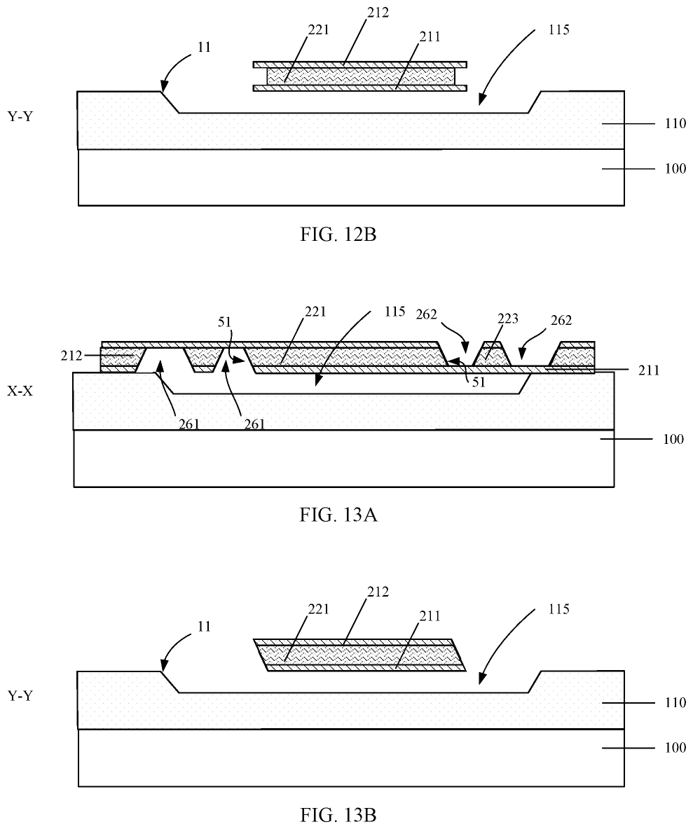

Further, after etching, the first piezoelectric oscillation plate 221 may also be reduced to a size within the overlapping region of the first electrode 211 and the second electrode 212. FIGS. 12A and 12B show schematic views of a structure consistent with various embodiment of the present disclosure.

Therefore, the first electrode 211 and the second electrode 212 may laterally extend out from the corresponding edge of the first piezoelectric oscillation plate 221. That is, on the basis of the structure shown in FIG. 11A, where the first electrode cavity 261 and the second electrode cavity 262 each includes a sidewall formed by the first piezoelectric oscillation plate 221, the first electrode cavity 261 and the second electrode cavity 262 may extend toward each other to occupy a portion of the width of the first piezoelectric oscillation plate 221.

It should be noted that those skilled in the art should know the proper etching processes (i.e., step S13, S16) performed on the first piezoelectric oscillation plate 221, and the details are not discussed here.

By reducing the width of the first piezoelectric oscillation plate 221, the first electrode 211, the second electrode 212, and the space formed by removing a portion of the first electrode 211 and the second electrode 212 may further suppress standing waves and other undesired signals, such that the filtering performance may be improved.

FIGS. 13A and 13B illustrate schematic views of another structure consistent with various embodiment of the present disclosure. Referring to FIGS. 13A and 13B, in some embodiments, after etching the first piezoelectric oscillation plate 221, the edges of the first piezoelectric oscillation plate 221, the first electrode 211, and/or the second electrode 212 may become tilted. That is, the edges of the first piezoelectric oscillation plate 221, the first electrode 211, and/or the second electrode 212 may not be perpendicular to the film layers.

For example, referring to FIG. 13A, the sidewall of the second electrode cavity 262 may be tilted such that the upper width of the second electrode cavity 262 may be larger than the lower width. Accordingly, when forming the first electrode cavity 261, the first electrode cavity 261 may also have a similar structure as the second electrode cavity 262.

Based on the principle of the present disclosure, those skilled in the art should know how to perform the etching process (i.e., step S13 and step S16) on the first piezoelectric oscillation plate 211. The details of the etching process will not be described in the present disclosure.

By forming sidewalls of the first electrode cavity and the second electrode cavity to be tilted, the direction of the reflected standing waves and spurious waves may be changed, the standing wave oscillation may be reduced, and the noise signal generated in the film BAWR may be reduced, such that the filtering performance may be improved.

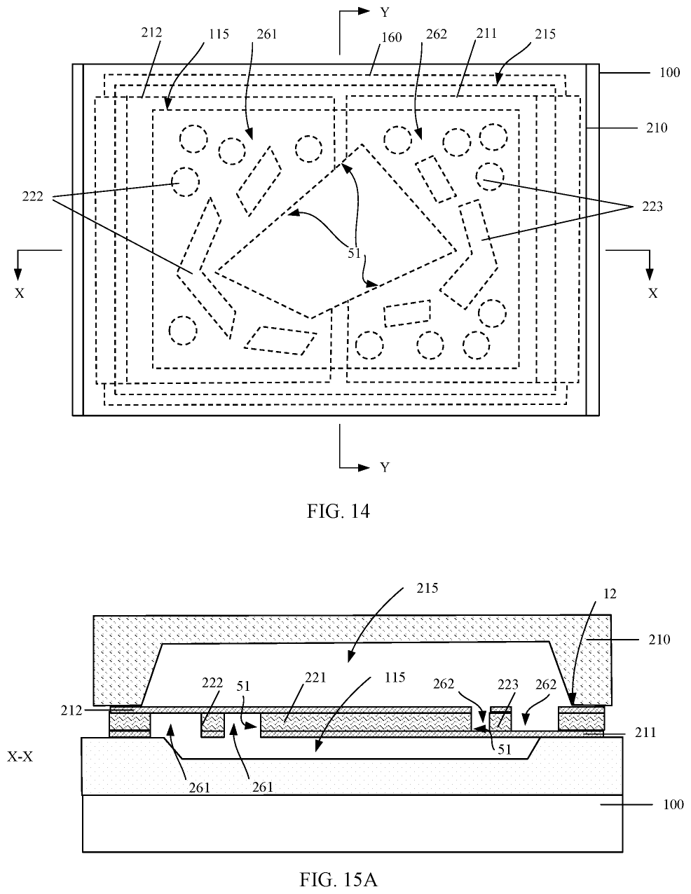

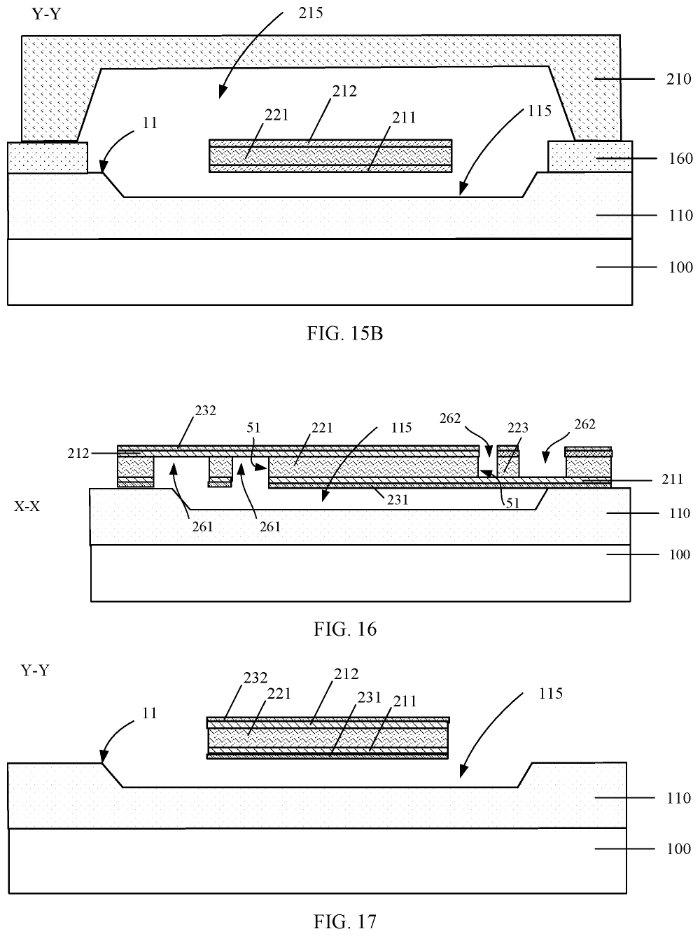

FIG. 14 illustrates a schematic top view of an exemplary film BAWR according to some embodiments of the present disclosure. FIG. 15A illustrates a schematic cross-sectional view of the structure shown in FIG. 14 along an X-X direction, and FIG. 15B illustrates a schematic cross-sectional view of the structure shown in FIG. 14 along a Y-Y direction.

Referring to FIGS. 14-15B, the fabrication method may further include the following exemplary steps.

A second insulating material layer 210 may be provided. In one embodiment, the second insulating material layer 210 may be fabricated on a second substrate (not shown).

A second cavity 215 may be formed in the second insulating material layer 210.

Further, the second insulating material layer 210 and the first substrate 100 may be bonded together through the second conductive film (i.e. the second electrode 212). The second cavity 215 and the first cavity 115 may be located on the two opposite sides of the device oscillation plate (i.e., the acoustic-wave resonant plate) formed by the first electrode 211, the piezoelectric oscillation plate 221, and the second electrode 212. The first piezoelectric oscillation plate 221 and the first piezoelectric-oscillation-plate boundary 51 may be completely enclosed within a second-cavity boundary 12 of the second cavity 215.

In one embodiment, the second piezoelectric-oscillation-plate boundary 52 may not have any portion parallel to any portion of the second-cavity boundary 12 and/or the third piezoelectric-oscillation-plate boundary 53 may not have any portion parallel to any portion of the second-cavity boundary 12.

In one embodiment, the second piezoelectric oscillation plates 222 and the second piezoelectric-oscillation-plate boundary 52 may be completely enclosed within the second-cavity boundary 12 and/or the third piezoelectric oscillation plates 223 and the third piezoelectric-oscillation-plate boundary 53 may be completely enclosed within the second-cavity boundary 12.

Referring to FIG. 15b, because of the absence of supporting structure along the Y-Y line, a second dielectric layer 160 may be formed on the first substrate 100 to not only facilitate the bonding process, but also provide protection for the oscillation plates and electrodes in the film BAWR.

FIGS. 16-17 illustrate schematic cross-sectional views of another exemplary film

BAWR according to some embodiments of the present disclosure. Referring to FIGS. 16-17, in one embodiment, the method for fabricating the film BAWR may further include forming a second temperature compensation film 232 between the sacrificial substrate 300 and the second conductive film 202, and forming a first temperature compensation film 231 on the first conductive film 201. Forming the second temperature compensation film 232 and the first temperature compensation film 231 may be completed in step S12 as illustrated in FIG. 3.

Accordingly, when etching the first conductive film 201 and the piezoelectric film 205, the first temperature compensation film 231 may be etched first, and when etching the second conductive film 202 and the piezoelectric film 205, the second temperature compensation film 232 may be etched first. Those skilled in the art should know and perform the etching process correctly.

Through the exemplary fabrication steps described above, a film BAWR according to the embodiments of the present disclosure may be obtained. The film BAWR may include a first substrate 100, and a first insulating material layer 110 disposed on the first substrate 100. A first cavity 115 may be formed on the side surface of the first insulating material layer 110 far away from the first substrate 100.

The film BAWR may also include a first electrode 211 and a second electrode 212 stacked on the first insulating material layer 110. The first electrode 211 may include a first electrode cavity 261 located above the first cavity 115, and the second electrode 212 may include a second electrode cavity 262 located above the first cavity 115.

The film BAWR may further include a first piezoelectric oscillation plate 221 disposed above the first cavity 115 and between the first electrode 211 and the second electrode 212. The bottom and the top surfaces of the first piezoelectric oscillation plate 221 may be attached to the first electrode 211 and the second electrode 212, respectively. The boundary of the first piezoelectric oscillation plate 211 may be a first piezoelectric-oscillation-plate boundary 51, and at least a portion of the first piezoelectric-oscillation-plate boundary 51 may be an overlapping region of a portion of the boundary of the first electrode cavity 261 and a portion of the boundary of the second electrode cavity 262. The first piezoelectric-oscillation-plate boundary 51 may have an irregular polygonal shape without having any two edges parallel to each other, and may be completely enclosed within a first-cavity boundary 11 of the first cavity 115.

The film BAWR may also include a plurality of second piezoelectric oscillation plates 222 and a plurality of third piezoelectric oscillation plates 223 formed above at least a portion of the first cavity 115 and between the first electrode 211 and the second electrode 212. For each second piezoelectric oscillation plate 222 or each third piezoelectric oscillation plate 223, the bottom and the top surfaces may be attached to the first electrode 211 and the second electrode 212, respectively. The plurality of second piezoelectric oscillation plates 222 and the plurality of third piezoelectric oscillation plates 223 may receive and absorb a portion of the vibration energy transmitted out through the vibration waves induced in the first electrode 211 and the second electrode 212.

In one embodiment, the boundary of the plurality of second piezoelectric oscillation plates 222 may be a second piezoelectric-oscillation-plate boundary 52, and the second piezoelectric-oscillation-plate boundary 52 may include at least a pair of parallel edges. The boundary of the plurality of third piezoelectric oscillation plates 223 may be a third piezoelectric-oscillation-plate boundary 52, and the third piezoelectric-oscillation-plate boundary 52 may also include at least a pair of parallel edges.

In one embodiment, the second piezoelectric-oscillation-plate boundary 52 and the third piezoelectric-oscillation-plate boundary 53 may not have any portion parallel to any portion of the first piezoelectric-oscillation-plate boundary 51. That is, for each edge on the first piezoelectric-oscillation-plate boundary 51, the second piezoelectric-oscillation-plate boundary 52 and the third piezoelectric-oscillation-plate boundary 53 may not have any edge parallel to the edge. As such, standing wave reflections can be avoided.

In one embodiment, the second piezoelectric oscillation plates 222 and the second piezoelectric-oscillation-plate boundary 52 may be completely enclosed within the first-cavity boundary 11 and/or the third piezoelectric oscillation plates 223 and the third piezoelectric-oscillation-plate boundary 53 may be completely enclosed within the first-cavity boundary 11.

In one embodiment, the second piezoelectric-oscillation-plate boundary 52 may not have any portion parallel to any portion of the first-cavity boundary 11 and/or the third piezoelectric-oscillation-plate boundary 53 may not have any portion parallel to any portion of the first-cavity boundary 11.

The plurality of second piezoelectric oscillation plates 222 and the plurality of third piezoelectric oscillation plates 223 may actually serve as a damper or a standing-wave absorber, and can also be used to provide boundary mechanical support.

The film BAWR may further include a second insulating material layer 210 formed on the second electrode 212. The second insulating material layer 210 may include a second cavity 215 with an opening facing the first piezoelectric oscillation plate 221. The second cavity 215 and the surface of the second insulating material layer 210 may form a second-cavity boundary 12.

In one embodiment, the first piezoelectric oscillation plate 221 and the first piezoelectric-oscillation-plate boundary 51 may be completely enclosed within the second-cavity boundary 12.

In one embodiment, the second piezoelectric-oscillation-plate boundary 52 may not have any portion parallel to any portion of the second-cavity boundary 12 and/or the third piezoelectric-oscillation-plate boundary 53 may not have any portion parallel to any portion of the second-cavity boundary 12.

In one embodiment, the second piezoelectric oscillation plates 222 and the second piezoelectric-oscillation-plate boundary 52 may be completely enclosed within the second-cavity boundary 12 and/or the third piezoelectric oscillation plates 223 and the third piezoelectric-oscillation-plate boundary 53 may be completely enclosed within the second-cavity boundary 12.

In one embodiment, the first piezoelectric oscillation plate 221, the plurality of second piezoelectric oscillation plates 222, and the plurality of third piezoelectric oscillation plates 223 may be made of a material including at least one of oxide, nitride, and carbide.

In one embodiment, the first piezoelectric oscillation plate 221, the plurality of second piezoelectric oscillation plates 222, and the plurality of third piezoelectric oscillation plates 223 may be made of a material including at least one of piezoelectric crystal or piezoelectric ceramic. For example, the material including at least one of piezoelectric crystal or piezoelectric ceramic may include at least one of quartz, lithium gallate, lithium germanate, titanium germanate, lithium niobate, lithium tantalate, aluminum nitride, zinc oxide, and lead-zinc titanite.

In one embodiment, the first electrode 211 and the second electrode 212 may be made of a metal or alloy including at least one of Al, Cu, Ni, W, Ti, Mo, Ag, Au, Pt, etc.

According to the disclosed film BAWR, the entire resonator is disposed above the first cavity 115 of the first insulating material layer 110. The resonator includes the following three layers.

The first layer of the resonator is a first electrode layer, i.e., the first electrode 211. The boundary of the first electrode layer may be a first electrode boundary.

The second layer of the resonator is a piezoelectric layer. The piezoelectric layer may include a first piezoelectric oscillation plate 221. The boundary of the first piezoelectric oscillation plate 221 may be the first piezoelectric-oscillation-plate boundary 51. The first piezoelectric oscillation plate 221 may be the core for generating piezoelectric oscillation. The piezoelectric layer may also include two attached mass blocks, i.e., the plurality of discrete second piezoelectric oscillation plates 222 and the plurality of discrete third piezoelectric oscillation plates 223. The plurality of second piezoelectric oscillation plates 222 and the plurality of third piezoelectric oscillation plates 223 may be formed using the same thin-film processing, photolithography, and etching procedure as the first piezoelectric oscillation plate 221. Instead of responsible for generating piezoelectric oscillation, the plurality of second piezoelectric oscillation plates 222 and the plurality of third piezoelectric oscillation plates 223 may be able to reduce the vibration. The boundaries of the plurality of second piezoelectric oscillation plates 222 and the plurality of third piezoelectric oscillation plates 223 may be the second piezoelectric-oscillation-plate boundary 52 and the third piezoelectric-oscillation-plate boundary 53, respectively.

The third layer of the resonator is a second electrode layer, i.e., the second electrode 212. The boundary of the second electrode layer may be a second electrode boundary.

The overlapping region of the orthogonal projections of the first electrode 211 and the second electrode 212 may be a first electrode-overlapping region, i.e., a region defined by the intersection of the first electrode boundary and the second electrode boundary. In the region defined by the intersection of the first electrode boundary and the second electrode boundary, the first piezoelectric oscillation plate 221 is the core for generating piezoelectric oscillation.

Under the electric field between the first electrode 211 and the second electrode 22, the first piezoelectric oscillation plate 221 may generate longitudinal piezoelectric oscillations such that vertical (longitudinal) bulk vibration waves, i.e., acoustic waves may be generated in the first piezoelectric oscillation plate 221. In the meantime, due to the physical Poisson effect, the first piezoelectric oscillation plate 221 may also generate spurious horizontal (lateral) bulk vibration, i.e., acoustic vibration, and may form transmitting echoes at the boundary of the first piezoelectric oscillation plate 221. In order to eliminate the standing waves formed by the reflected echoes, the boundary of the first piezoelectric oscillation plate 221 may have an irregular polygonal shape without having any two edges parallel to each other.

However, the vertical and the horizontal vibration waves in the first piezoelectric oscillation plate 221 may both induce vertical and horizontal vibration waves in the lower and the upper electrodes, i.e., the first electrode 211 and the second electrode 212, and the vertical and the horizontal vibration waves in the lower and the upper electrodes may be transmitted out. When a specific reflective boundary is encountered, the vibration induced in the lower and the upper electrodes may generate reflected waves and return back to the electrode regions on the first piezoelectric oscillation plate 221. As such, secondary response waves may be induced in the first piezoelectric oscillation plate 221. In particular, regenerated secondary standing waves may be generated, resulting in noise signals.

According to the embodiments of the present disclosure, the return of the vibration waves induced in the upper and the lower electrodes may be substantially suppressed due to the following reasons.

A portion of the vibration waves induced in the upper and the lower electrodes may be ‘absorbed’ externally, such that the energy of the returning waves may be reduced. For example, ‘suspended’ mass blocks, such that the plurality of second piezoelectric oscillation plates 222 and the plurality of third piezoelectric oscillation plates 223, may be disposed outside of the first piezoelectric oscillation plate 221 to receive and absorb a portion of the vibration energy transmitted out through vibration waves induced in the upper and the lower electrodes.

Further, a portion of the vibration waves induced in the upper and the lower electrodes may be possibly ‘restrained’ to the outside, such that the energy of the returning waves may be reduced. Because the second piezoelectric oscillation plates 222 and the third piezoelectric oscillation plates 223 all have at least a pair of parallel edges, after receiving and absorbing a portion of the vibration energy transmitted out through the vibration waves induced in the upper and the lower electrodes, standing wave reflection may be generated inside the second piezoelectric oscillation plates 222 and the third piezoelectric oscillation plates 223, such that the reception and absorption of the energy of the vibration waves may be effectively ‘restrained’.

The disclosed acoustic wave resonator may also include a first temperature compensation film 231 disposed above the first cavity 115 and on the surface of the first electrode 211 far away from the first piezoelectric oscillation plate 221. The thermal expansion coefficient of the first temperature compensation film 231 may be lower than the thermal expansion coefficient of the first electrode 211 and/or the thermal expansion coefficient of the second electrode 212.

For example, the first temperature compensation film 231 may be made of a material including at least one of oxide, nitride, and carbide.

The disclosed acoustic wave resonator may also include a second temperature compensation film 232 disposed above the first cavity 115 and on the surface of the second electrode 212 far away from the first piezoelectric oscillation plate 221. The thermal expansion coefficient of the second temperature compensation film 232 may be lower than the thermal expansion coefficient of the first electrode 211 and/or the thermal expansion coefficient of the second electrode 212.

For example, the second temperature compensation film 232 may be made of a material including at least one of oxide, nitride, and carbide.

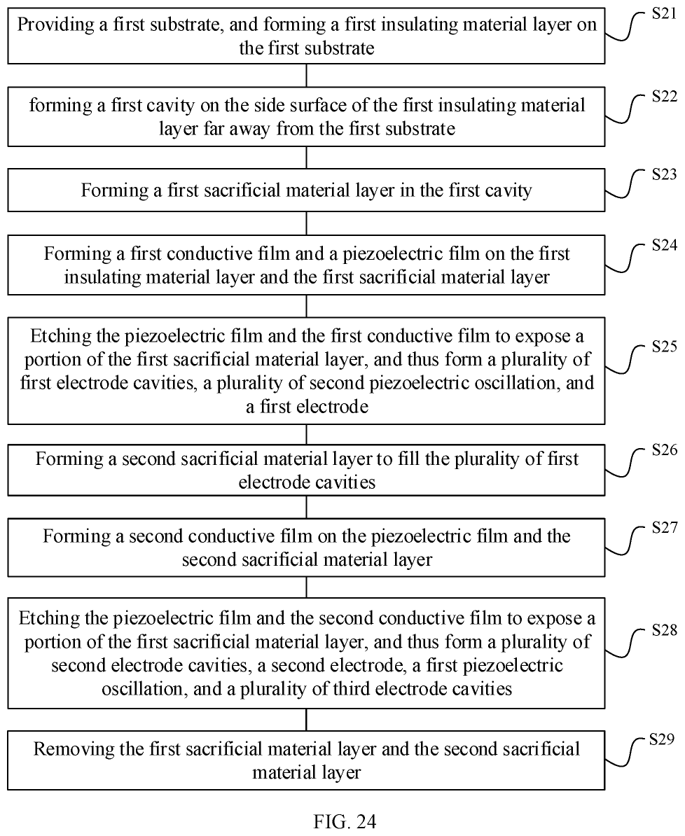

The present disclosure also provides another fabrication method for film BAWR. FIG. 24 illustrates a flowchart of an exemplary fabrication method for a film BAWR according to another embodiment of the present disclosure, and FIGS. 18-23 illustrate schematic views of structures at certain stages of the method for fabricating the film BAWR according to an embodiment of the present disclosure.

Referring to FIG. 24, at the beginning of the fabrication process, a first substrate may be provided, and a first insulating material layer may be formed on the first substrate (S21). FIG. 18 illustrates a schematic cross-sectional view of a structure consistent with some embodiments of the present disclosure.

Referring to FIG. 18, in step S21, a first substrate 100 may be provided. A first insulating material layer 110 may be formed on the first substrate 100. The first substrate 100 may be made of any appropriate material known to those skilled in the art. For example, the first substrate 100 may be a single-crystalline silicon substrate, a silicon germanium substrate, a germanium substrate, or any other appropriate semiconductor substrate known to those skilled in the art. According to actual needs, the first substrate 100 may include a buried structure, or a well region formed by ion implantation. In other embodiments, a plurality of CMOS active devices and other electrically-interconnected components may be formed on the first substrate 100.

In one embodiment, the first insulating material layer 110 may be made of at least one of oxide, nitride, and carbide. For example, the first insulating material layer 110 may be made of silicon oxide, silicon nitride, silicon carbide, SiON, or any other appropriate material.

In one embodiment, the first insulating material layer 110 may be made of silicon oxide. The first insulating material layer 110 may be formed through a CVD process. Alternatively, the first insulating material layer 110 may be formed using a thermal oxidation method, or any other appropriate method.

Further, returning to FIG. 24, a first cavity may be formed on the side surface of the first insulating material layer far away from the first substrate (S24). Referring to FIG. 18, in step S22, a first cavity (not shown) may be formed on the side surface of the first insulating material layer 110 far away from the first substrate 100.

In one embodiment, the first cavity may be formed through a wet etching process, a dry etching process, or a process combining the wet etching and the dry etching. The first cavity may not be limited to any specific shape. For example, the first cavity may have any appropriate shape, such as a rectangular shape, or other polygonal shape. The first cavity may not be limited to any specific size either. For example, the height, the side length, the occupied area, etc. of the first cavity may be determined according to the actual needs.

Further, returning to FIG. 24, a first sacrificial material layer may be formed in the first cavity (S23). Referring to FIG. 18, in step S23, a first sacrificial material layer 451 may be formed on the first cavity. The top surface of the first sacrificial material layer 451 may be leveled with the top surface of the first insulating material layer 110.

In one embodiment, the first sacrificial material layer 451 may be made of, for example, silicon oxide, carbon-rich dielectric, germanium, hydrocarbon polymer, amorphous carbon, etc. In one embodiment, the first sacrificial material layer 451 may be made of amorphous carbon. It should be noted that the first sacrificial material layer 451 may be made of a material not limited to those listed above; instead, the first sacrificial material layer 451 may be made of any appropriate material known to those skilled in the art.

In one embodiment, the surface of the first sacrificial material layer 451 may be leveled with the surface of the first insulating material layer 110 through a planarization process.

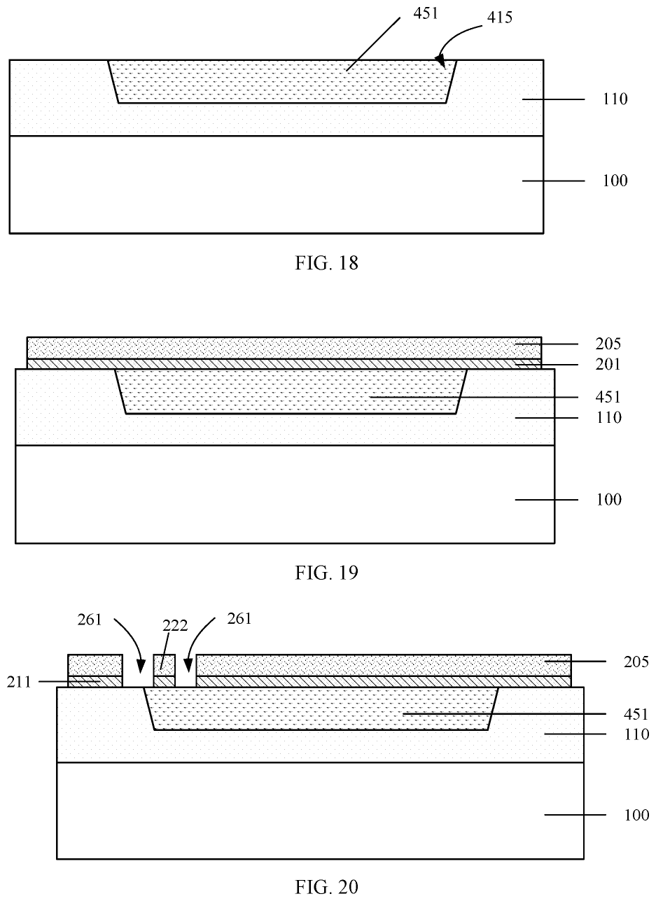

Further, returning to FIG. 24, a first conductive film and a piezoelectric film may be formed on the first insulating material layer and the first sacrificial material layer (S24). FIG. 19 illustrates a schematic cross-sectional view of a structure consistent with various embodiments of the present disclosure.

Referring to FIG. 19, in step S24, a first conductive film 201 and a piezoelectric film 205 may be formed on the first insulating material layer 110 and the first sacrificial material layer 451.

In one embodiment, the first conductive film 201 may be made of a metal or alloy including at least one of Al, Cu, Ni, W, Ti, Mo, Ag, Au, Pt, etc. The piezoelectric film 205 may be made of at least one of quartz, lithium gallate, lithium germanate, titanium germanate, lithium niobate, lithium tantalate, aluminum nitride, zinc oxide, and lead-zinc titanite.

Further, returning to FIG. 24, the piezoelectric film and the first conductive film may be etched to expose a portion of the first sacrificial material layer, and thus form a first electrode cavity, a plurality of second piezoelectric oscillation plates, and a first electrode (S25). FIG. 20 illustrates a schematic cross-sectional view of a structure consistent with various embodiments of the present disclosure.

Referring to FIG. 20, in step S25, the piezoelectric film 205 and the first conductive film 201 (referring to FIG. 19) may be etched to expose a portion of the first sacrificial material layer 451, and thus form a first electrode cavity 261, a plurality of second piezoelectric oscillation plates 222, and a first electrode 211.

In one embodiment, the piezoelectric film 205 and the first conductive film 201 may be etched through an etching process using a photolithography method. For the details of the etching process, reference may be made to the corresponding description in embodiments provided above.

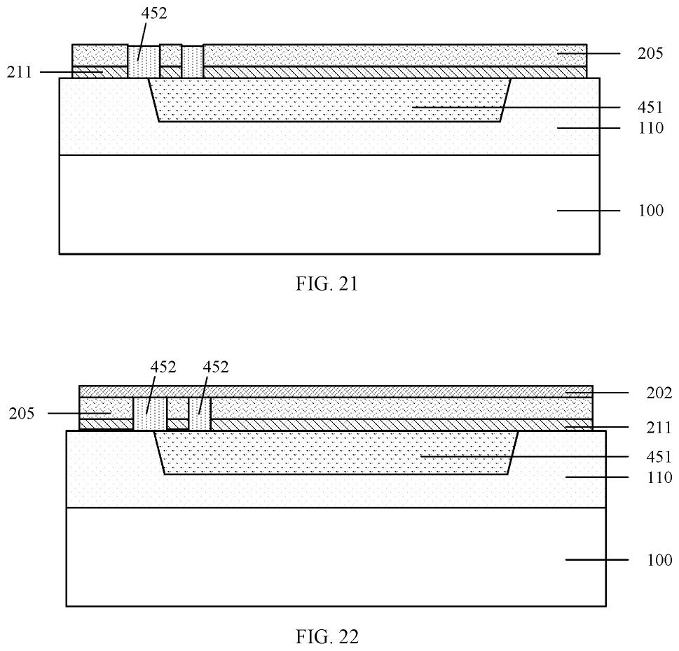

Further, returning to FIG. 24, a second sacrificial material layer may be formed to fill the first electrode cavity (S26). FIG. 21 illustrates a schematic cross-sectional view of a structure consistent with various embodiments of the present disclosure.

Referring to FIG. 21, in step S26, a second sacrificial material layer 452 may be formed to fill the first electrode cavity 261 (referring to FIG. 20).

In one embodiment, the second sacrificial material layer 452 may be made of silicon oxide, carbon-rich dielectric material, germanium, hydrocarbon polymer, or amorphous silicon. In one embodiment, the second sacrificial material layer 452 may be made of amorphous carbon. It should be noted that the material selection for the second sacrificial material layer 452 may not be limited to the materials list above, any appropriate material known to those skilled in the art may be used to form the second sacrificial material layer 452.

In one embodiment, the second sacrificial material layer 452 may be initially formed on the piezoelectric film 205 and also filling the first electrode cavity. Then, the portion of the second sacrificial material layer 452 formed on the piezoelectric film 405 may be removed, and the portion of the second sacrificial material layer 452 formed in the first electrode cavity may remain. As such, the second sacrificial material layer may be able to fill up the first electrode cavity.

Further, returning to FIG. 24, a second conductive film may be formed on the piezoelectric film and the second sacrificial material layer (S27). FIG. 22 illustrates a schematic cross-sectional view of a structure consistent with various embodiments of the present disclosure.

Referring to FIG. 22, in step S27, a second conductive film 202 may be formed on the piezoelectric film 205 and the second sacrificial material layer 452. In one embodiment, the second conductive film 202 may be formed through a CVD process.

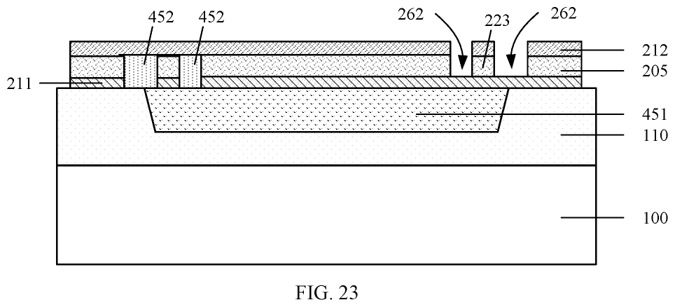

Further, returning to FIG. 24, the second conductive film and the piezoelectric film may be etched to expose a portion of the first conductive film, and thus form a second electrode cavity, a second electrode, a first piezoelectric oscillation plate, and a plurality of third piezoelectric oscillation plates (S28). FIG. 23 illustrates a schematic cross-sectional view of a structure consistent with various embodiments of the present disclosure.

Referring to FIG. 23, in step S28, the second conductive film 202 (referring to FIG. 22) and the piezoelectric film 205 may be etched to expose a portion of the first conductive film (i.e., the first electrode 211), and thus form a second electrode cavity 262, a second electrode 212, a first piezoelectric oscillation plate 221, and a plurality of third piezoelectric oscillation plates 223.

After forming the second electrode cavity 262, the second electrode 212, the first piezoelectric oscillation plate 221, the top view of the structure may be consistent with the top view shown in FIG. 10. Compared to the structure formed using the previous method described above, the structure formed here includes the first sacrificial layer 451 filling the first cavity and the second sacrificial layer 452 filling the first electrode cavity.

Therefore, returning to FIG. 24, the first sacrificial material layer and the second sacrificial material layer may be removed to form the film BAWR (S29). After removing the first sacrificial material layer and the second sacrificial material layer, the obtained structure is consistent with the structure illustrated in FIGS. 11A and 11B.

Referring to FIGS. 11A and 11B, based on the structure shown in FIG. 23, the first sacrificial material layer 451 and the second sacrificial material layer 452 may be removed.

In one embodiment, the boundary of the first piezoelectric oscillation plate 221 may be the first piezoelectric-oscillation-plate boundary 51, and at least a portion of the first piezoelectric-oscillation-plate boundary 51 may be an overlapping region of a portion of the boundary of the first electrode cavity 261 and a portion of the boundary of the second electrode cavity 262. The first piezoelectric-oscillation-plate boundary 51 may have an irregular polygonal shape without having any two edges parallel to each other, and may be completely enclosed within a first-cavity boundary 11 of the first cavity 115. The plurality of second piezoelectric oscillation plates 222 and the plurality of third piezoelectric oscillation plates 223 may receive and absorb a portion of the vibration energy transmitted out through the vibration waves induced in the first electrode 211 and the second electrode 212.

Similarly, by initially forming sacrificial material layers to occupy the cavities during the fabrication process, structures consistent with those shown in FIGS. 12A and 12B and in FIGS. 13A and 13B can also be fabricated.

In the formed film BAWRs, the boundary of the first piezoelectric oscillation plate 221 may be the first piezoelectric-oscillation-plate boundary 51, and the first piezoelectric-oscillation-plate boundary 51 may have an irregular polygonal shape without having any two edges parallel to each other. The first piezoelectric-oscillation-plate boundary 51 may be entirely enclosed in the first cavity boundary 11. The plurality of second piezoelectric oscillation plates 222 and the plurality of third piezoelectric oscillation plates 223 may receive and absorb a portion of vibration energy transmitted out through the vibration waves induced in the first electrode 211 and the second electrode 212.

Further fabrication steps according to the method described here may be substantially similar to those steps according to the previous method described above. For the details of the further steps according to the method described here, reference may be made to the corresponding description in the embodiments of the previous method.

Therefore, according to the embodiments of the method described here, a sacrificial layer is formed in the first cavity, and then a first electrode cavity and a second electrode cavity may be sequentially formed without penetrating through the piezoelectric oscillation structure. The first electrode cavity and the second electrode cavity may partially overlap with each other. As such, the sacrificial layer formed in the first cavity can be removed through the first electrode cavity and/or the second electrode cavity. Therefore, the fabrication method may be flexible. Compared to the method according to the existing technology, where a through hole 90 is formed through both the upper and the lower electrodes as shown in FIG. 1, the disclosed method may be able to have a piezoelectric-oscillation-plate boundary that does not contain any parallel edges. As such, the performance of the film BAWR may be significantly improved.

Accordingly, the functions and the advantages of the embodiments according to the method described here may be the same as or may be similar to that of the embodiments according to the method described previously.

Further, compared to the existing technology, the film BAWR and the fabrication method may demonstrate several advantages.

The first piezoelectric oscillation plate sandwiched between the first electrode and the second electrode is fully disposed above the first cavity. The boundary of the first piezoelectric oscillation plate may have a polygonal shape without having any two edges parallel to each other. As such, not only the additional standing wave oscillations that become clutter in the horizontal direction may be eliminated, but also the energy consumed by the lateral spurious waves may be minimized. In the meantime, besides the first piezoelectric oscillation plate, a plurality of ‘suspended’ second piezoelectric oscillation plates and a plurality of ‘suspended’ third piezoelectric oscillation plates are disposed to receive and absorb a portion of the vibration energy transmitted out through the vibration waves induced in the upper and the lower electrodes. As such, the filtering performance of the film BAWR, including the quality factor, may be effectively improved.

Further, each second piezoelectric oscillation plate or each third piezoelectric oscillation plate is designed to contain at least a pair of parallel edges, so that standing wave reflection can be generated inside the second piezoelectric oscillation plate or the third piezoelectric oscillation plate. Therefore, the reception and absorption of the energy of vibration waves may be effectively ‘restrained’, and thus the noise signals can be more effectively reduced.

The above detailed descriptions only illustrate certain exemplary embodiments of the present invention, and are not intended to limit the scope of the present invention. Those skilled in the art can understand the specification as whole and technical features in the various embodiments can be combined into other embodiments understandable to those persons of ordinary skill in the art. Any equivalent or modification thereof, without departing from the spirit and principle of the present invention, falls within the true scope of the present invention.

What is claimed is:

1. A film bulk acoustic wave resonator (BAWR), comprising:
a first substrate;
a first insulating material layer, formed on the first substrate;
a first cavity, formed in the first insulating material layer with an opening facing away from the first substrate, wherein the first cavity forms a first cavity boundary at a surface of the first insulating material layer;
a first electrode and a second electrode stacked on the first insulating material layer, wherein the first electrode includes a first electrode cavity formed above the first cavity, and the second electrode includes a second electrode cavity formed above the first cavity;
a first piezoelectric oscillation plate sandwiched between the first electrode and the second electrode, and having a first piezoelectric-oscillation-plate boundary, wherein at least a portion of the first piezoelectric-oscillation-plate boundary is an overlapping region of a portion of a boundary of the first electrode cavity and a portion of a boundary of the second electrode cavity, and the first piezoelectric-oscillation-plate boundary has an irregular polygonal shape without having any two edges parallel to each other, and is entirely enclosed in the first cavity boundary;
a plurality of second piezoelectric oscillation plates and a plurality of third piezoelectric oscillation plates disposed at least partially above the first cavity and sandwiched between the first electrode and the second electrode, wherein the plurality of second piezoelectric oscillation plates and the plurality of third piezoelectric oscillation plates receive and absorb a portion of vibration energy transmitted out through vibration waves induced in the first electrode and the second electrode.

2. The film BAWR according to claim 1, wherein:
the plurality of second piezoelectric oscillation plates have a second piezoelectric-oscillation-plate boundary including at least one pair of parallel edges; and
the plurality of third piezoelectric oscillation plates have a third piezoelectric-oscillation-plate boundary including at least one pair of parallel edges.

3. The film BAWR according to claim 2, wherein:
any portion of the second piezoelectric-oscillation-plate boundary is not parallel to any portion of the first piezoelectric-oscillation-plate boundary;
the plurality of second piezoelectric oscillation plates and the second piezoelectric-oscillation-plate boundary are entirely enclosed in the first cavity boundary;
any portion of the second piezoelectric-oscillation-plate boundary is not parallel to any portion of the first cavity boundary;
any portion of the third piezoelectric-oscillation-plate boundary is not parallel to any portion of the first piezoelectric-oscillation-plate boundary;
the plurality of third piezoelectric oscillation plates and the third piezoelectric-oscillation-plate boundary are entirely enclosed in the first cavity boundary; and
any portion of the third piezoelectric-oscillation-plate boundary is not parallel to any portion of the first cavity boundary.

4. The film BAWR according to claim 3, wherein:
the plurality of second piezoelectric oscillation plates and/or the plurality of third piezoelectric oscillation plates provide boundary mechanical support.

5. The film BAWR according to claim 2, further including a second insulating material layer disposed above the second electrode, wherein:
a second cavity, with an opening facing the first piezoelectric oscillation plate, is formed in the second insulating material layer; and
the second cavity forms a second cavity boundary at a surface of the second insulating material layer.

6. The film BAWR according to claim 5, wherein:
the first piezoelectric oscillation plate and the first piezoelectric-oscillation-plate boundary are entirely enclosed in the second cavity boundary;
any position of the second piezoelectric-oscillation-plate boundary is not parallel to any portion of the second cavity boundary, and/or any position of the third piezoelectric-oscillation-plate boundary is not parallel to any portion of the second cavity boundary; and
the plurality of second piezoelectric oscillation plates and the second piezoelectric-oscillation-plate boundary are entirely enclosed in the second cavity boundary, and/or the plurality of third piezoelectric oscillation plates and the third piezoelectric-oscillation-plate boundary are entirely enclosed in the second cavity boundary.

7. The film BAWR according to claim 1, wherein:
the first electrode and the second electrode are made of a material including at least one of Al, Cu, Ni, W, Ti, Mo, Ag, Au, and Pt; and
the first piezoelectric oscillation plate, the plurality of second piezoelectric oscillation plates, and the plurality of third piezoelectric oscillation plates are made of a material including at least one of piezoelectric crystal or piezoelectric ceramic.

8. The film BAWR according to claim 7, wherein:
the first piezoelectric oscillation plate, the plurality of second piezoelectric oscillation plates, and the plurality of third piezoelectric oscillation plates are made of a material including at least one of quartz, lithium gallate, lithium germanate, titanium germanate, lithium niobate, lithium tantalate, aluminum nitride, zinc oxide, and lead-zinc titanite.

9. The film BAWR according to claim 1, further including:
a first temperature compensation film formed above the first cavity and on a surface of the first electrode far away from the first piezoelectric oscillation plate, wherein:
the first temperature compensation film is made of a material including at least one of oxide, nitride, and carbide,
a thermal expansion coefficient of the first temperature compensation film is lower than thermal expansion coefficients of the first electrode and the second electrode.

10. The film BAWR according to claim 1, further including:
a second temperature compensation film formed above the first cavity and on a surface of the second electrode far away from the first piezoelectric oscillation plate, wherein:
the second temperature compensation film is made of a material including at least one of oxide, nitride, and carbide,
a thermal expansion coefficient of the second temperature compensation film is lower than thermal expansion coefficients of the first electrode and the second electrode.

11. A method for fabricating a film BAWR, comprising:
forming a first insulating material layer on a first substrate;
forming a first cavity in the first insulating material layer with an opening facing away from the first substrate;
sequentially forming a second conductive film, a piezoelectric film, and a first conductive film on a sacrificial substrate;
etching a portion of the first conductive film and the piezoelectric film close to an end of the sacrificial substrate to expose a portion of the second conductive film, a remaining portion of the first conductive film becoming a first electrode, a plurality of trenches formed through the first conductive film and the piezoelectric film becoming a plurality of first electrode cavities, and a portion of the piezoelectric film located between adjacent first electrode cavities becoming a plurality of second piezoelectric oscillation plates;
bonding the first substrate and the sacrificial substrate together by bonding the first insulating material layer to the first conductive film, wherein after bonding, the plurality of first electrode cavities are located above the first cavity;
removing the sacrificial substrate; and
etching a portion of the second conductive film and a portion of the piezoelectric film close to an end of the sacrificial substrate opposite to the end where the plurality of first electrode cavities are formed to expose a portion of the first electrode, a remaining portion of the second conductive film becoming a second electrode, a remaining portion of the piezoelectric film sandwiched between the first electrode and the second electrode becoming a first piezoelectric oscillation plate, a plurality of trenches formed through the second conductive film and the piezoelectric film becoming a plurality of second electrode cavities, and a portion of the piezoelectric film located between adjacent second electrode cavities becoming a plurality of third piezoelectric oscillation plates, wherein:
the first piezoelectric oscillation plate has a first piezoelectric-oscillation-plate boundary,
at least a portion of the first piezoelectric-oscillation-plate boundary is an overlapping region of a portion of a boundary of the first electrode cavity and a portion of a boundary of the second electrode cavity,
the first piezoelectric-oscillation-plate boundary has an irregular polygonal shape without having any two edges parallel to each other, and is entirely enclosed in the first cavity boundary, and
the plurality of second piezoelectric oscillation plates and the plurality of third piezoelectric oscillation plates receive and absorb a portion of vibration energy transmitted out through vibration waves induced in the first electrode and the second electrode.

12. The method for fabricating the film BAWR according to claim 11, wherein:
the plurality of second piezoelectric oscillation plates have a second piezoelectric-oscillation-plate boundary including at least one pair of parallel edges; and
the plurality of third piezoelectric oscillation plates have a third piezoelectric-oscillation-plate boundary including at least one pair of parallel edges.

13. The method for fabricating the film BAWR according to claim 11, wherein:
any portion of the second piezoelectric-oscillation-plate boundary is not parallel to any portion of the first piezoelectric-oscillation-plate boundary;
the plurality of second piezoelectric oscillation plates and the second piezoelectric-oscillation-plate boundary are entirely enclosed in the first cavity boundary;
any portion of the second piezoelectric-oscillation-plate boundary is not parallel to any portion of the first cavity boundary;
any portion of the third piezoelectric-oscillation-plate boundary is not parallel to any portion of the first piezoelectric-oscillation-plate boundary;
the plurality of third piezoelectric oscillation plates and the third piezoelectric-oscillation-plate boundary are entirely enclosed in the first cavity boundary; and
any portion of the third piezoelectric-oscillation-plate boundary is not parallel to any portion of the first cavity boundary.

14. The method for fabricating the film BAWR according to claim 13, wherein:
the plurality of second piezoelectric oscillation plates and/or the plurality of third piezoelectric oscillation plates provide boundary mechanical support.

15. The method for fabricating the film BAWR according to claim 11, further including:
when forming the second conductive film, the piezoelectric film, and the first conductive film on the sacrificial substrate, forming a second temperature compensation film between the sacrificial substrate and the second conductive film, and a first temperature compensation film on the first conductive film;
prior to etching the portion of the first conductive film and the portion of the piezoelectric film to expose the second conductive film, etching a portion of the first temperature compensation film; and
prior to etching the portion of the second conductive film and the portion of the piezoelectric film to expose the first electrode, etching a portion of the second temperature compensation film.

16. The method for fabricating the film BAWR according to claim 11, further including:
providing a second insulating material layer;
forming a second cavity in the second insulating material layer, wherein the second cavity forms a second cavity boundary at a surface of the second insulating material layer; and
bonding the second insulating material layer to the second electrode on the first substrate, wherein an opening of the second cavity faces the second electrode, and the first piezoelectric oscillation plate and the first piezoelectric-oscillation-plate boundary are entirely enclosed in the second cavity boundary.

17. The method for fabricating the film BAWR according to claim 16, wherein:
any position of the second piezoelectric-oscillation-plate boundary is not parallel to any portion of the second cavity boundary, and/or any position of the third piezoelectric-oscillation-plate boundary is not parallel to any portion of the second cavity boundary; and
the plurality of second piezoelectric oscillation plates and the second piezoelectric-oscillation-plate boundary are entirely enclosed in the second cavity boundary, and/or the plurality of third piezoelectric oscillation plates and the third piezoelectric-oscillation-plate boundary are entirely enclosed in the second cavity boundary.

18. A method for fabricating a film BAWR, comprising:
forming a first insulating material layer on a first substrate;
forming a first cavity in the first insulating material layer with an opening facing away from the first substrate;
forming a first sacrificial material layer in the first cavity, wherein a top surface of the first sacrificial material layer is leveled with a top surface of the first insulating material layer;
sequentially forming a first conductive film and a piezoelectric film on the first insulating material layer and the first sacrificial material layer;
etching a portion of the piezoelectric film and a portion of the first conductive film above the first sacrificial material layer to expose a portion of the first sacrificial material layer, a plurality of trenches formed through the piezoelectric film and the first conductive film becoming a plurality of first electrode cavities, a remaining portion of the first conductive film becoming a first electrode, and a portion of the piezoelectric film located between adjacent first electrode cavities becoming a plurality of second piezoelectric oscillation plates;
forming a second sacrificial material layer to fill the plurality of first electrode cavities;
forming a second conductive film on the piezoelectric film and the second sacrificial material layer;
etching a portion of the second conductive film and a portion of the piezoelectric film formed above the first sacrificial material layer to expose a portion of the first electrode, a remaining portion of the second conductive film becoming a second electrode, a remaining portion of the piezoelectric film sandwiched between the first electrode and the second electrode becoming a first piezoelectric oscillation plate, a plurality of trenches formed through the second conductive film and the piezoelectric film becoming a plurality of second electrode cavities, and a portion of the piezoelectric film located between adjacent second electrode cavities becoming a plurality of third piezoelectric oscillation plates; and
removing the first sacrificial material layer and the second sacrificial material layer, wherein:
the first piezoelectric oscillation plate has a first piezoelectric-oscillation-plate boundary,
at least a portion of the first piezoelectric-oscillation-plate boundary is an overlapping region of a portion of a boundary of the first electrode cavity and a portion of a boundary of the second electrode cavity,
the first piezoelectric-oscillation-plate boundary has an irregular polygonal shape without having any two edges parallel to each other, and the first piezoelectric-oscillation-plate boundary is entirely enclosed in the first cavity boundary, and
the plurality of second piezoelectric oscillation plates and the plurality of third piezoelectric oscillation plates receive and absorb a portion of vibration energy transmitted out through vibration waves induced in the first electrode and the second electrode.

19. The method for fabricating the film BAWR according to claim 18, further including:
forming a second insulating material layer on a second substrate;
forming a second cavity in the second insulating material layer with an opening facing away from the second substrate; and
bonding the second substrate and the first substrate together by bonding the second insulating material layer to the first insulating material layer, wherein:
the first piezoelectric oscillation plate has a first piezoelectric-oscillation-plate boundary,
at least a portion of the first piezoelectric-oscillation-plate boundary is an overlapping region of a portion of a boundary of the first electrode cavity and a portion of a boundary of the second electrode cavity,
the first piezoelectric-oscillation-plate boundary has an irregular polygonal shape without having any two edges parallel to each other, and the first piezoelectric-oscillation-plate boundary is entirely enclosed in the first cavity boundary, and
the plurality of second piezoelectric oscillation plates and the plurality of third piezoelectric oscillation plates receive and absorb a portion of vibration energy transmitted out through vibration waves induced in the first electrode and the second electrode.

20. The method for fabricating the film BAWR according to claim 18, further including:
providing a second insulating material layer;
forming a second cavity in the second insulating material layer, wherein the second cavity forms a second cavity boundary at a surface of the second insulating material layer; and
bonding the second insulating material layer to the second electrode on the first substrate, wherein an opening of the second cavity faces the second electrode, and the first piezoelectric oscillation plate and the first piezoelectric-oscillation-plate boundary are entirely enclosed in the second cavity boundary.
